(19) United States
(12) Patent Application Publication
(10) Pub. No.: US 2007/0064406 A1
(43) Pub. Date: Mar. 22, 2007

(54) Inductive power transfer units having flux shields

(76) Inventor: Pilgrim G. W. Beart, Cambridge (GB)

Correspondence Address: STITES & HARBISON PLLC, 1199 NORTH FAIRFAX STREET, SUITE 900, ALEXANDRIA, VA, 22314, US

(21) Appl. No.: 10/570,761

(22) PCT Filed: Sep. 8, 2004
(86) PCT No.: PCT/GB04/03844

§ 371 Date: Oct. 24, 2006

(30) Foreign Application Priority Data
Sep. 8, 2003 (GB) 0320960.8

(51) Int. Cl. H05K 9/00

(52) U.S. Cl. 361/816

(57) ABSTRACT

An inductive power transfer unit is adapted to be placed when in use on a support surface (200). A flux generating unit (50) extends in two dimensions over the support surface, and generates flux at or in proximity to a power transfer surface of the unit so that a secondary device placed on or in proximity to the power transfer surface can receive power inductively from the unit. A flux shield (70), made of electrically-conductive material, is interposed between the flux generating unit and the support surface, the shield extending outwardly (e₁−e₄) beyond at least one edge of the flux generating unit. Alternatively, the flux shield may have one or more portions which extend over one or more side faces of the inductive power transfer unit or which extend between the side face(s) and the flux generating unit. The flux shield may be supplied as a removable accessory which attaches to the outside of the inductive power transfer unit.

This invention relates to inductive power transfer units having flux shields.

Inductive power transfer units, as described for example in the present applicant's published International patent publication no. WO-A-03/096512, the entire contents of which is hereby incorporated into the present application by reference, seek to provide a flat or curved power transfer surface over which a substantially horizontal alternating magnetic field flows. This field couples into any secondary devices placed upon the power transfer surface. In some variants this field may rotate in the plane of the surface to provide complete freedom of positioning for any secondary device placed on the surface to receive power. The secondary devices are, for example, built into portable electrical or electronic devices or rechargeable batteries which can be removed from the surface when not receiving power.

Depending on the design of the flux generating unit (magnetic assembly) of such power transfer units, they may also emit flux in directions other than desired horizontal surface field. For example a “squashed solenoid” design of flux generating unit emits flux symmetrically above and below it.

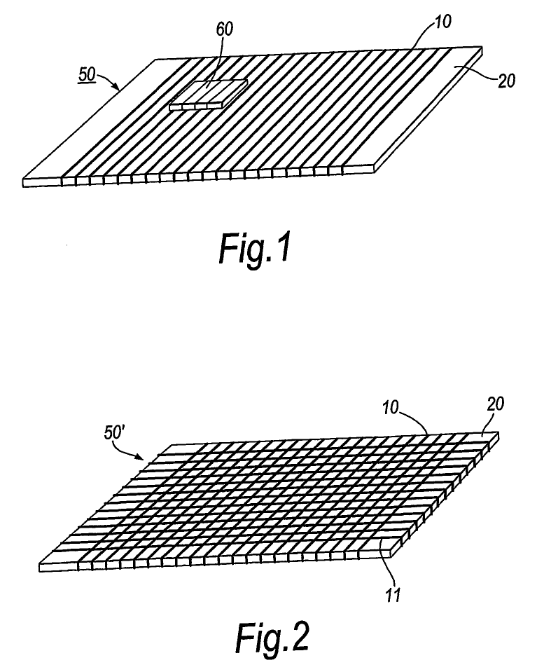

In FIG. 1, a flux generating unit 50 comprises a coil 10 shaped into a flat solenoid wound around a former 20. The former 20 is in the form of a thin sheet of magnetic material. This results in a substantially horizontal field across the upper surface of the flux generating unit, but also an equal field across the lower surface. The field lines of both fields extend generally in parallel with one another over the respective surfaces, substantially perpendicularly to the coil windings. A secondary device 60 is shown in place over the upper surface.

FIG. 2 shows a similar arrangement to that of FIG. 1, but with an additional coil 11 wound, in an orthogonal direction to the winding direction of the coil 10, around the former 20. By driving the two coils 10 and 11 in a suitable manner, the flux generating unit may create a field which is substantially horizontal over the power transfer surface (upper surface) and which rotates in the plane of that surface. In typical usage, the flux above the upper surface provides the functionality that the user desires (powering the secondary device 60 ), but the flux present at other surfaces may not be useful and can cause undesired effects.

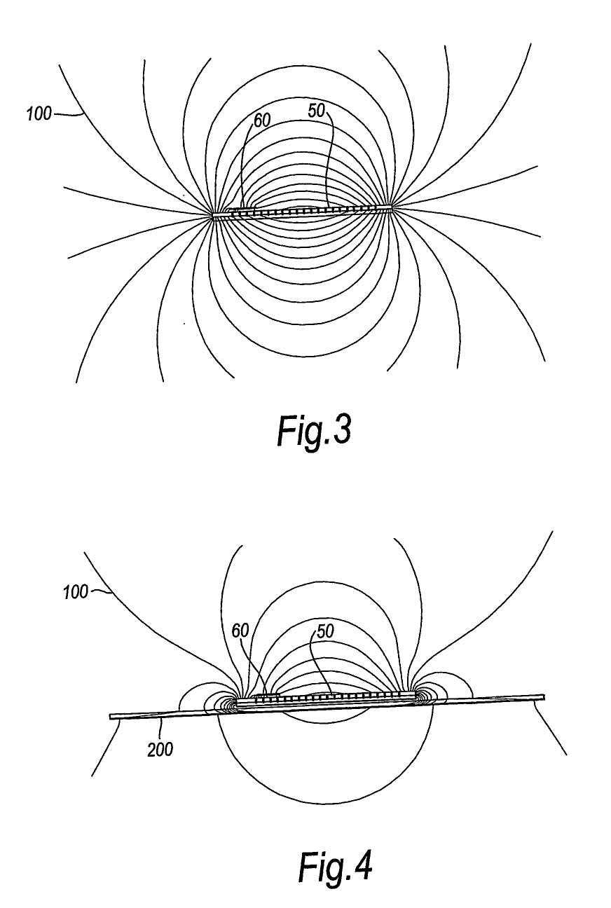

FIG. 3 shows a side view Finite Element analysis of the flux lines generated by the flux generating unit 50 in FIG. 1 at an instant in time. The lines travel through the centre of the solenoid and then divide to return over and under it through the air. A secondary device 60 is shown placed on top of the unit 50.

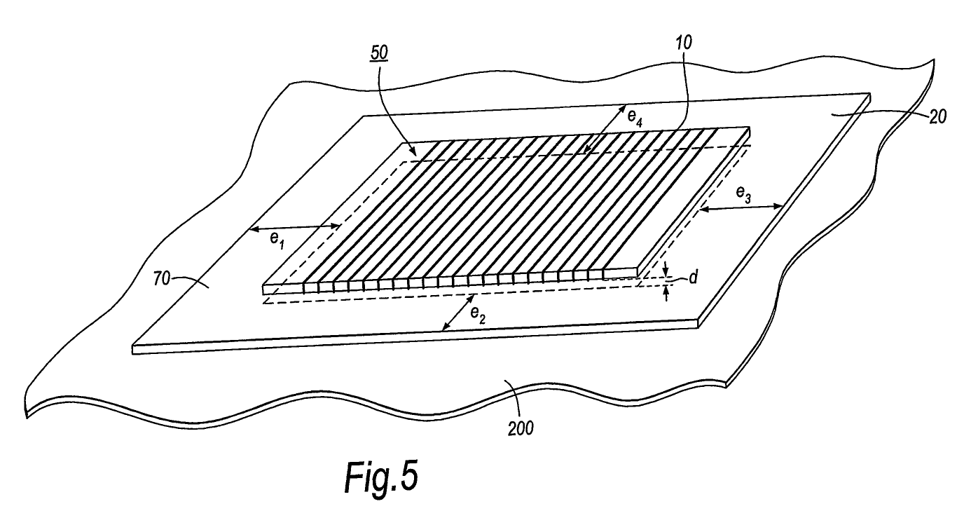

One undesired effect occurs particularly when the primary unit is placed upon a ferrous metal surface, for example a mild steel desk or part of a vehicle chassis. The permeability of mild steel is sufficiently high that it provides a return path for the flux which is of considerably lower reluctance than the alternative path through air. Therefore the flux is “sucked” down into the metal desk. FIG. 4 shows another Finite Element analysis view when a metal desk 200 is brought under the flux generating unit. The high permeability of the metal offers the flux lines a much lower-reluctance path than air to return from one end of the flux generating unit 50 to the other, and so they travel within the desk rather than through the air. This is undesirable for two reasons:
A significant proportion of the flux generated by the inductive power transfer unit (primary unit) is flowing into the metal desk instead of flowing into any secondary devices on the upper surface of the unit, therefore the system becomes less efficient (consumes the more power) and the power received by the secondary device varies.
The flux flowing through the metal desk causes core losses, for example via hysteresis and/or eddy current loss , which cause it to heat up.

It is known that when conductive materials, for example copper or aluminum, are placed into an alternating magnetic field, the field induces eddy-currents to circulate within them. The eddy currents then act to generate a second field which—in the limit of a perfect conductor—is equal and opposite to the imposed field, and cancels it out at the surface of the conductor. Therefore these conductive materials can be seen as “flux-shields”—the lines of flux in any magnetic system are excluded from them. This may be used to shield one part of a system from a magnetic field and consequently concentrate the field in another part. GB-A-2389720, which is a document published after the priority date of the present application but having an earlier priority date, discloses a flux generating unit in the form of a printed circuit board having an array of spiral conductive tracks for generating flux above the upper surface of the unit. A ferrite sheet is placed under the board, and a conductive sheet is placed under the ferrite sheet, to provide a flux shield. The ferrite sheet and conductive sheet are of the same dimensions, parallel to the sheets, as the board.

According to a first aspect of the present invention there is provided an inductive power transfer unit, adapted to be placed when in use on a support surface, comprising: a flux generating means which, when the unit is placed on the support surface, extends in two dimensions over the support surface, said flux generating means being operable to generate flux at or in proximity to a power transfer surface of the unit so that a secondary device placed on or in proximity to the power transfer surface can receive power inductively from the unit; and a flux shield, made of electrically-conductive material, arranged so that when the unit is placed on the support surface, the shield is interposed between the flux generating means and the support surface, the shield extending outwardly beyond at least one edge of the flux generating means.

According to a second aspect of the present invention there is provided an inductive power transfer unit, adapted to be placed when in use on a support surface, comprising: a flux generating means which, when the unit is placed on the support surface, extends in two dimensions over the support surface, said flux generating means being operable to generate flux at or in proximity to a power transfer surface of the unit so that a secondary device placed on or in proximity to the power transfer surface can receive power inductively from the unit; and a flux shield, made of electrically-conductive material, having one or more portions which extend over one or more side faces of the unit or which extend between said one or more side faces and said flux generating means.

In cases where the flux generating unit operates by creating a field which alternates back and forth in one linear dimension, the conductive shield will have induced in it an equal and opposite alternating linear field, which acts to cancel the field near the shield. In cases where the unit operates by creating a rotating field in the plane of its laminar surface, the conductive shield has induced in it a field which also rotates, again cancelling the field.

Such power transfer units are advantageous because they allow the flux to be concentrated in directions in which it is useful, improving the flux-efficiency of the unit, and to be shielded from directions where it can cause side-effects, for example by coupling into a metal desk under the unit.

In addition, the flux shield increases the coupling between the flux generating unit and the secondary device(s) by forcing most of the flux to go over the power transfer surface. Therefore less drive current is needed in the flux generating unit to create a given flux density in the secondary device(s). Accordingly, provided that losses in the flux shield are minimized, the system as a whole becomes more efficient.

To ensure that the apparatus runs cool and is power-efficient, I²R losses (losses caused by circulating currents dissipating as heat) in the conductive shield must be kept small:
The conductive shield is advantageously made of a highly conductive material, for example copper or aluminum sheet of sufficient thickness to ensure that the eddy-currents induced therein do not suffer from excessive resistance and therefore create heat. The flux density, and therefore the eddy currents, may vary across different parts of the apparatus, and therefore the necessary thickness, or material, may also vary.
The spacing between the shield and the electrically-driven conductors of the flux generating unit can be optimized. The larger it is (i.e. the greater the spacing between it and the electrically-driven conductors), the lower the current-density induced in the conductive shield, and therefore the lower the heating. However this must be traded-off against the larger the overall dimensions necessary which may be less ergonomic.

In addition, the conductive shield must not itself be substantially ferrous, otherwise it may provide a low-reluctance path which “shorts” the intended flux path.

In one embodiment of the present invention, the conductive shield extends in a substantially continuous sheet substantially over all but one face of the flux generating unit, such that only the face substantially exposed is the laminar surface intended for power delivery to secondary devices. For example, if the generating unit is a substantially flat rectangular shape, the shield may extend to cover the bottom and four sides of the unit. As another example, if the flux generating unit is a substantially flat cylinder, the shield may extend to cover the bottom and cylindrical side of the unit. The advantage of such an arrangement is that it increases still further, compared to a flat sheet, the path that flux would have to travel in order to travel through a metal object undeneath flux generating unit.

In another embodiment of the present invention, the conductive shield may enclose all but a part of one or more faces of the flux generating unit. For example, if the flux generating unit is a substantially flat rectangular shape, the shield may cover the bottom, sides and outer part of the top of the flux generating unit. This may be advantageous in controlling the flux pattern at the edge of the top of the flux generating unit.

The conductive shield may form part of an enclosure of the inductive power transfer unit, for example a formed or cast aluminum or magnesium casing. This may be advantageous in reducing cost.

According to a third aspect of the present invention there is provided an inductive power transfer unit comprising: a power transfer surface on or in proximity to which a secondary device can be placed to receive power inductively from the unit; flux generating means arranged to generate flux at or in proximity to said power transfer surface; and flux shield attachment means arranged for attaching a flux shield to the unit such that the attached shield is arranged at one or more external surfaces of the unit other than said power transfer surface, or is arranged between said one or more external surfaces and said flux generating means, so that the shield serves to shield objects outside the unit, adjacent to said one or more external surfaces, from flux generated by the flux generating means.

According to a fourth aspect of the present invention there is provided an accessory, adapted to be attached to the outside of an inductive power transfer unit, the unit having a power transfer surface on or in proximity to which a secondary device can be placed to receive power inductively from the unit and also having flux generating means arranged to generate flux at or in proximity to the power transfer surface, and the accessory comprising: means which co-operate with the unit to attach the accessory to the outside of the unit in a predetermined working disposition; and a flux shield, made of electrically-conductive material, which, when the accessory is in its said working disposition, extends at or in proximity to one or more external surfaces of the unit other than said power transfer surface so as to shield objects outside the unit, adjacent to said one or more external surfaces, from flux generated by the flux generating means.

In the third and fourth aspects of the invention the conductive shield is supplied to the user as a separate accessory to be placed under or around the power transfer unit. Optionally it may be provided as a retainable accessory, for example a clip-on cover. This is advantageous as it allows the bill of materials for the power transfer unit to be kept to an absolute minimum, yet allows users to purchase the accessory if the unit is to be used in a location where it may be necessary to constrain its field, for example on a ferrous metal desk.

In one embodiment the flux generating unit comprises at least one means for generating an electromagnetic field, the means being distributed in two dimensions across a predetermined area in or parallel to the power transfer surface so as to define at least one power transfer area of the power transfer surface that is substantially coextensive with the predetermined area, the charging area having a width and a length on the power transfer-surface. Preferably the means is configured such that, when a predetermined current is supplied thereto and the primary unit is effectively in electromagnetic isolation, an electromagnetic field generated by the means has electromagnetic field lines that, when averaged over any quarter length part of the power transfer area measured parallel to a direction of the field lines, subtend an angle of 45° or less to the power transfer surface in proximity thereto and are distributed in two dimensions thereover. Preferably the means has a height measured substantially perpendicular to the power transfer area that is less than either of the width or the length of the power transfer area. The height is more preferably less than one fifth, or less than one tenth, of either the width or height, so that the inductive power transfer unit as a whole is in the form of a flat bed or platform. When a secondary device, including at least one electrical conductor, is placed on or in proximity to a power transfer area of the inductive power transfer unit, the electromagnetic field lines couple with the at least one conductor of the secondary device and induce a current to flow therein. The conductive sheet or shield is arranged on or in the power transfer unit at a location other than the side on which the power transfer area is located.

In the context of the present application, the word “laminar” defines a geometry in the form of a thin sheet or lamina. The thin sheet or lamina may be substantially flat, or may be curved.

It is to be appreciated that the conductive sheet or shield may be generally laminar, or may include one or more edge portions that are directed towards the power transfer surface.

The conductive sheet or shield may be exposed on the side of the power transfer unit opposed to the power transfer surface, or may be covered with a layer of dielectric or other material, for example by part of a casing of the unit.

For a better understanding of the present invention and to show how it may be carried into effect, reference shall now be made, by way of example, to the accompanying drawings, in which:

FIG. 1 is a perspective view showing an example of a flux generating unit suitable for use in embodiments of the present invention.

FIG. 2 is a perspective view showing another example of a flux generating unit suitable for use in embodiments of the present invention.

FIG. 3 shows a side view of the flux generating unit of FIG. 1 for illustrating flux lines generated thereby.

FIG. 4 is a view corresponding to FIG. 3 but illustrating flux lines generated when a metal desk is present under the arrangement.

FIG. 5 is a perspective view showing parts of an inductive power transfer unit according to a first embodiment of the present invention.

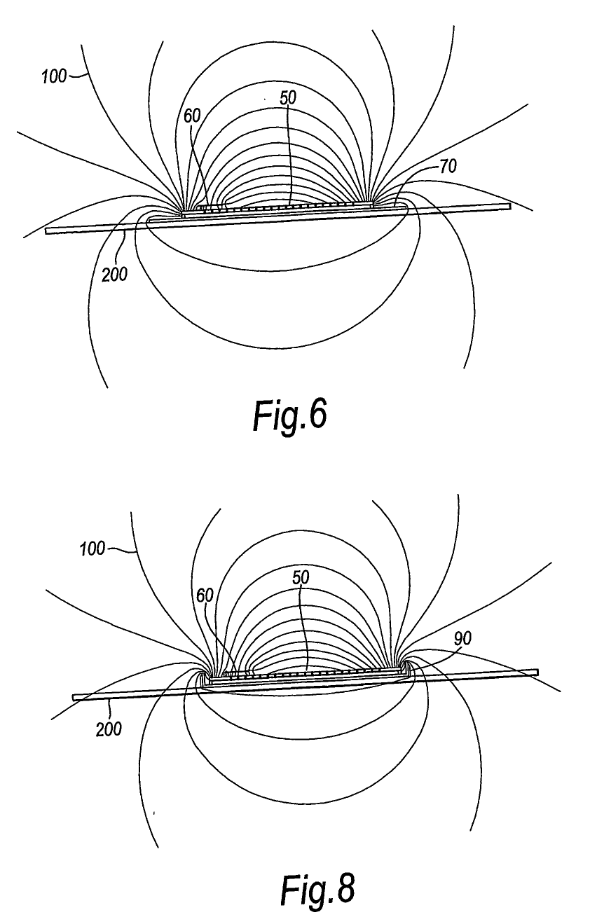

FIG. 6 shows a side view of the unit of FIG. 5 for illustrating flux lines generated thereby when the unit is placed on a metal desk.

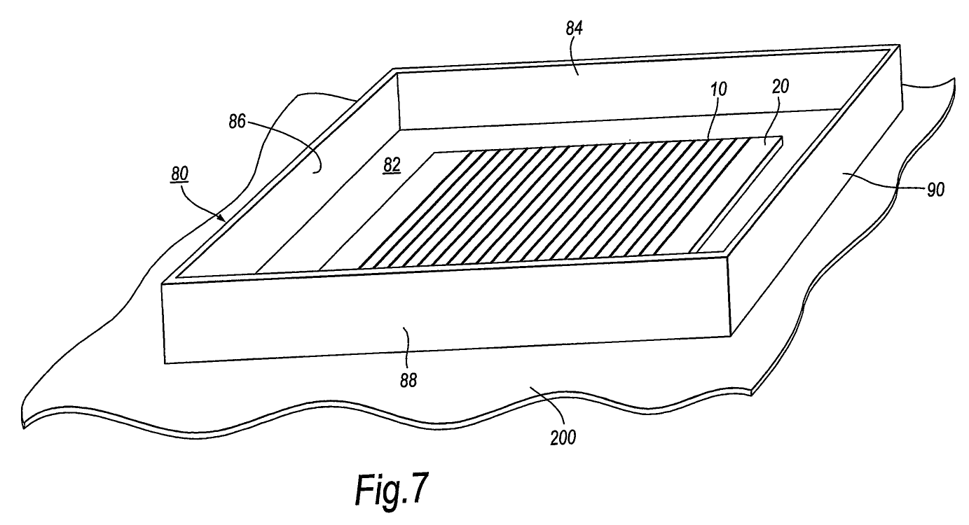

FIG. 7 is a perspective view showing parts of an inductive power transfer unit according to a second embodiment of the present invention.

FIG. 8 shows a side view of the unit of FIG. 7 for illustrating flux lines generated thereby when the unit is placed on a metal desk.

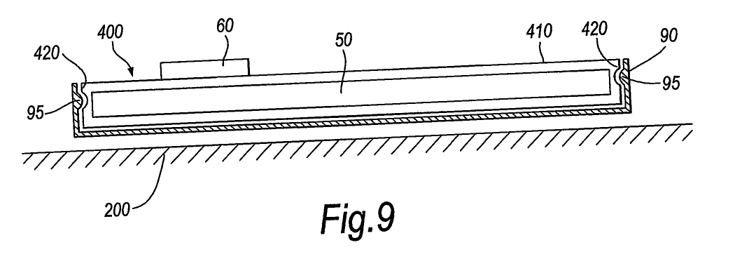

FIG. 9 is a side view of an inductive power transfer unit and an accessory therefor according to a third embodiment of the present invention.

FIG. 5 shows parts of an inductive power transfer unit according to a first embodiment of the present invention. In this embodiment, a flux generating unit 50 has the same general construction as the flux generating unit described in the introduction with reference to FIG. 1. Of course a flux generating unit 50′ as shown in FIG. 2 can be used in this (and other) embodiments of the invention, instead. Similarly, any of the flux generating units described in WO-A-03/096512 can be used in embodiments of the present invention.

The flux generating unit 50 comprises a coil 10 wound around a former 20. The former 20 is in the form of a thin sheet of magnetic material. When the inductive power transfer unit is placed on a support surface 200, the flux generating unit 50 extends in two dimensions over the support surface.

A flux shield 70, made of electrically-conductive material such as copper, is interposed between the flux generating unit 50 and the support surface 200. As shown in FIG. 5, the shield 70 extends outwardly by distances e₁ to e₄ beyond each edge of the flux generating unit 50. The distance e₁ is for example 50 mm. The distance e₂ is for example 50 mm. The distance e₃ is for example 50 mm. The distance e₄ is for example 50 mm.

In this embodiment, the flux shield 70 is in the form of a flat sheet which extends generally in parallel with the support surface. There is a gap of size d between the sheet and the electrical conductors of the coil 10 extending over the lower surface of the former 20. d is 4 mm, for example.

FIG. 6 shows a Finite Element analysis view of the unit of FIG. 5. The support 200 is assumed to be a metal desk. The shield 70 forces any flux lines flowing through the metal desk to travel around the shield, increasing the path length and thus the effective reluctance of the “desk” path. As a result, the presence of the desk has less effect, since more flux lines travel over the unit instead of going through the desk. Although the flux shield 70 has extensions beyond all edges of the unit 50 in the FIG. 5 example, it will be appreciated that a worthwhile flux-shielding effect can also be obtained even if the flux shield extends beyond one edge or only extends beyond a pair of opposite edges, FIG. 7 shows parts of an inductive power transfer unit according to a second embodiment of the present invention. In this embodiment a flux shield 80 having 5 sides (base 82 and side walls 84, 86, 88 and 90) is provided. The base 82 of the flux shield 80 extends between the lower surface of the flux generating unit 50 and the support surface 200. Because the flux shield 80 has side walls in this embodiment, the base 82 need not extend out beyond the edges of the flux generating unit 50 by as far as the distances e₁ to e₄ in the FIG. 5 embodiment. For example, e₁ to e₄ may each be 4 mm. This can enable the overall dimensions of the power transfer unit to be reduced while keeping the effective reluctance of the desk path high. The height of the side walls 84, 86, 88 and 90 is exaggerated in FIG. 7 for clarity. In practice, the side walls need not extend above the upper surface of the flux generating unit 50

The flux shield 80 may be formed from a flat sheet of conductive material which is cut and folded up at the edges to form a tray-form member.

FIG. 8 shows a finite element analysis view of the unit of FIG. 7.

FIG. 9 shows parts of an inductive power transfer unit 400 according to a third embodiment of the present invention. In this embodiment a flux generating unit 50, similar to the flux generating units described with reference to the first and second embodiments, is contained in a casing 410 of the unit 400. An upper surface of the casing 410 provides the power transfer surface in this embodiment, and a secondary device 60 is placed directly on the surface to receive power inductively from the flux generating unit 50.

In each of the four side walls of the casing 410 a small circular recess 420 is formed.

In this embodiment the flux shield 90 is an accessory which is adapted to be attached to the outside of the inductive power transfer unit 400. The flux shield 90, which is similar in form to the flux shield 80 shown in FIG. 7, has circular projections 95 formed on the inner surfaces of the upstanding side walls of the flux shield 90. The projections 95 engage respectively with the recesses 420 in the casing of the inductive power transfer unit 400. In this way, the unit 400 can be inserted into the flux shield 90 due to the resilience of the materials of the flux shield 90 and/or casing 410. The projections and recesses serve to hold the flux shield 90 on the outside of the unit 400 in such a way that the flux shield shields objects outside the unit, adjacent to the external surfaces of the unit, from flux generated by the flux generating unit 50.

The provision of a removable flux shield has several advantages. In some applications, the flux shield is unnecessary. For example, the shield is unnecessary if the support surface on which the unit will be placed is non-metallic. In this way, the unit can be made as small as possible and at the lowest possible cost. Any user who intends to use the unit on a metallic support surface can purchase the flux shield as an optional accessory.

When the flux shield is in the form of a removable accessory, it is not necessary for the flux shield to have the form of the first embodiment or second embodiment described above. For example, the flux shield need not extend outwardly beyond the edges of the flux generating unit 50; it could be coterminous with the planar area of the flux generating unit 50 or even smaller than the planar area thereof. For example, a flat sheet-form conductive shield could be built into the base of a tray-form plastics housing of the accessory.

Any suitable way of attaching the flux shield to the outside of the inductive power transfer unit may be used. Although snap-fitting is particularly convenient, the flux shield may be attached to the unit using screws or Velcro®. Equally, there could simply be a tight fit between the flux shield and the casing of the unit.

By way of example only, there now follows a set of test results for embodiments of this invention. In the test set up the flux generating unit 50 measured approximately 175×25×9 mm. The flux shield 70 or 80 was made from a 0.6 mm thick sheet of copper. The metal desk 200 was a sheet of metal 500 mm ×500 mm ×0.6 mm thick (magnetically, this is effectively an infinite plane).

The current through the flux generating unit 50 was adjusted so that the power delivered to a secondary device 60 was the same at the start of each test. A control loop then held the current constant during the rest of each test.

The power received by the secondary device was monitored and the extra power drawn from the charger was monitored.

The results were as follows:

| | | Power seen | Extra power |
|---|---|---|---|
| | | by secondary | needed from |
| Test Condition | | device | charger |
| 1a. | No flux shield | 100% | 0 W |
| 1b. | As 1a with steel under | 123% | 11 W |
| 2a. | Flux shield sheet (FIG. 5) | 100% | 1.5 W |
| | immediately under magnetic assembly | | |
| 2b. | Flux shield moved 4 mm from assembly | 100% | 0.7 W |
| 2c. | As 2b with steel under | 110% | 4.6 W |
| 3a. | Flux shield box (FIG. 7)around | 100% | 1.5 W |
| | bottom and edges (4 mm gap) | | |
| 3b. | As 3a with steel under | 108% | 2.2 W |

Test 1 shows the case without any flux shield. The flux lines will initially be approximately as shown in FIG. 3. Introducing a metal sheet under the assembly causes the flux to travel down and through the sheet, in preference to travelling up and over the top, as shown in FIG. 4. The control loop in the generator is forced to expend 11 W to keep its coil current constant, which is not optimal since it is inefficient and will cause the metal to warm up. In addition, the secondary device sees a rise in the power it receives to 123%, because eddy currents in the metal desk do act as a poor flux excluder even as they consume large amounts of generator power—and this is not optimal either. Test 2 shows the case with a flat flux shielding sheet underneath as in the first embodiment. A large (190 mm. ×140 mm ×0.6 mm) copper sheet flux shield immediately under the magnetic assembly (test 2a) causes the generator to have to supply an additional 1.5 W, presumably because it starts to short the coil turns in the assembly. Moving this 4 mm away from the assembly (i.e. d=4 mm in FIG. 5) reduces this drain to 0.7 W (test 2b). Now introducing a metal sheet only causes the generator to have to supply 4.6 W (i.e. an additional 3.9 W), and the power into the

secondary device now only changes to 110% (test 2c). This is shown in FIG. 6. So the flux shield has reduced each of the two side-effects by more than half.

Test 3 shows the case where the edges of the flux shield are brought up around the edges of the magnetic assembly, as in the second embodiment shown in FIG. 7. The shield is kept 4 mm away from the magnetic assembly on all sides (test 3a) to avoid the phenomenon seen in Test 2a. The generator must supply an additional 1.5 W to overcome the losses of the eddy currents in the shield. Now introducing a metal sheet (test 3b) only causes the generator to have to supply an extra 2.2 W (i.e. an additional 0.7 W), and the power seen by the secondary device now only changes to 108%.

In conclusion, these test results clearly demonstrate the two key advantages of a flux shield in reducing the side effects of metal objects: less power delivered into the steel by the generator, and less variation in the power seen by the secondary device.

A shield extending completely around the magnetic assembly, except over the desired power transfer surface, can reduce the effect of metal desks on the generator by more than an order of magnitude, and on the secondary device by more than half. In the example shown the price to pay for this advantage is an extra 1.54 W of quiescent power delivered by the generator, to overcome losses in the eddy-currents in the flux shield.

The preferred features of the invention are applicable to all aspects of the invention and may be used in any possible combination.

Throughout the description and claims of this specification, the words “comprise” and “contain” and variations of the words, for example “comprising” and “comprises”, mean “including but not limited to”, and are not intended to (and do not) exclude other components, integers, moieties, additives or steps.

1. An inductive power transfer unit, adapted to be placed when in use on a support surface, comprising:
a flux generating unit which, when the inductive power transfer unit is placed on the support surface, extends in two dimensions over the support surface, said flux generating unit being operable to generate flux at or in proximity to a power transfer surface of the inductive power transfer unit so that a secondary device placed on or in proximity to the power transfer surface can receive power inductively from the inductive power transfer unit; and
a flux shield, made of electrically-conductive material, arranged so that when the inductive power transfer unit is placed on the support surface, the shield is interposed between the flux generating unit and the support surface, the shield extending outwardly beyond at least one edge of the flux generating unit.

2. The inductive power transfer unit as claimed in claim 1, wherein said flux shield is in the form of a flat sheet which extends generally in parallel with the support surface.

3. The inductive power transfer unit as claimed in claim 1, wherein said flux shield extends outwardly beyond each edge of the flux generating unit.

4. An inductive power transfer unit, adapted to be placed when in use on a support surface, comprising:
a flux generating unit which, when the inductive power transfer unit is placed on the support surface, extends in two dimensions over the support surface, said flux generating unit being operable to generate flux at or in proximity to a power transfer surface of the inductive power transfer unit so that a secondary device placed on or in proximity to the power transfer surface can receive power inductively from the inductive power transfer unit; and
a flux shield, made of electrically-conductive material, having one or more portions which extend over one or more side faces of the inductive power transfer unit or which extend between said one or more side faces and said flux generating unit.

5. The inductive power transfer unit as claimed in claim 4, wherein said flux shield also extends over an outer peripheral portion of said power transfer surface or between said outer peripheral portion and said flux generating unit.

6. The inductive power transfer unit as claimed in claim 4, wherein said flux shield extends substantially continuously around said flux generating unit except for a part thereof adjacent to said power transfer surface.

7. The inductive power transfer unit as claimed in claim 4, wherein said flux shield provides at least part of a casing of the unit.

8. The inductive power transfer unit as claimed in claim 4, wherein at least part of an outer surface of the flux shield is covered with a dielectric or other material.

9. The inductive power transfer unit as claimed in claim 4, wherein a gap between said flux shield and electrical conductors of said flux generating unit is set so that flux shielding is achieved without the flux shield unduly increasing power consumption of the flux generating unit.

10. The inductive power transfer unit as claimed in claim 4, wherein said flux shield varies in thickness from one part to another.

11. The inductive power transfer unit as claimed in claim 4, wherein different parts of the flux shield are made from different respective materials.

12. The inductive power transfer unit as claimed in claim 4, wherein the flux shield is attached removably to the inductive power transfer unit.

13. An inductive power transfer unit comprising:
a power transfer surface on or in proximity to which a secondary device can be placed to receive power inductively from the inductive power transfer unit;
a flux generating unit arranged to generate flux at or in proximity to said power transfer surface; and
a flux shield attachment arrangement adapted to attach a flux shield to the inductive power transfer unit such that the attached shield is arranged at one or more external surfaces of the inductive power transfer unit other than said power transfer surface, or is arranged between said one or more external surfaces and said flux generating unit, so that the shield serves to shield objects outside the inductive power transfer unit, adjacent to said one or more external surfaces, from flux generated by the flux generating unit.

14. An accessory, adapted to be attached to the outside of an inductive power transfer unit, the inductive power transfer unit having a power transfer surface on or in proximity to which a secondary device can be placed to receive power inductively from the inductive power transfer unit and also having a flux generating unit arranged to generate flux at or in proximity to the power transfer surface, and the accessory comprising:
an attachment arrangement which cooperates with the inductive power transfer unit to attach the accessory to the outside of the inductive power transfer unit in a predetermined working disposition; and
a flux shield, made of electrically-conductive material, which, when the accessory is in its said working disposition, extends at or in proximity to one or more external surfaces of the inductive power transfer unit other than said power transfer surface so as to shield objects outside the inductive power transfer unit, adjacent to said one or more external surfaces, from flux generated by the flux generating unit.

15. The accessory as claimed in claim 14, adapted to be attached removably to the outside of the inductive power transfer unit.

16. The accessory as claimed in claim 14, being a clip-on cover for the inductive power transfer unit.

17. The accessory as claimed in claim 14, wherein, when the accessory is attached to the inductive power transfer unit in its working disposition and the accessory is placed on a support surface, the flux generating unit of the inductive power transfer unit extends in two dimensions over the support surface with the flux shield of the accessory interposed between the flux generating unit and the support surface, and the flux shield extends outwardly beyond at least one edge of the flux generating unit.

18. The accessory as claimed in claim 17, wherein said flux shield is in the form of a flat sheet which extends generally in parallel with the support surface.

19. The accessory as claimed in claim 17, wherein said flux shield extends outwardly beyond each edge of the flux generating unit.

20. The accessory as claimed in claim 14, wherein when said accessory is attached to the inductive power transfer unit in its said working disposition said flux shield also extends over one or more side faces of the inductive power transfer unit.

21. The accessory as claimed in claim 14, wherein when said accessory is attached to the inductive power transfer unit in its said working disposition said flux shield also extends over an outer peripheral portion of said power transfer surface of the inductive power transfer unit.

22. The inductive power transfer unit as claimed in claim 1, wherein said flux shield also extends over an outer peripheral portion of said power transfer surface or between said outer peripheral portion and said flux generating unit.

23. The inductive power transfer unit as claimed in claim 1, wherein said flux shield extends substantially continuously around said flux generating unit except for a part thereof adjacent to said power transfer surface.

24. The inductive power transfer unit as claimed in claim 1, wherein said flux shield provides at least part of a casing of the unit.

25. The inductive power transfer unit as claimed in claim 1, wherein at least part of an outer surface of the flux shield is covered with a dielectric or other material.

26. The inductive power transfer unit as claimed in claim 1, wherein a gap between said flux shield and electrical conductors of said flux generating unit is set so that flux shielding is achieved without the flux shield unduly increasing power consumption of the flux generating unit.

27. The inductive power transfer unit as claimed in claim 1, wherein said flux shield varies in thickness from one part to another.

28. The inductive power transfer unit as claimed in claim 1, wherein different parts of the flux shield are made from different respective materials.

29. The inductive power transfer unit as claimed in claim 1, wherein the flux shield is attached removably to the inductive power transfer unit.
